(19) United States
(12) Patent Application Publication
(10) Pub. No.: US 2026/0096059 A1
(43) Pub. Date: Apr. 2, 2026

(54) COOLANT LIQUID DRAIN WITH INTEGRATED LEAK DETECTION

(71) Applicant: DELL PRODUCTS L.P., Round Rock, TX (US)

(72) Inventors: Bhyrav Mutnury, Round Rock, TX (US); Sandor Farkas, Round Rock, TX (US); Michael Stumpf, Cedar Park, TX (US)

(21) Appl. No.: 18/901,253

(22) Filed: Sep. 30, 2024

(51) Int. Cl. H05K 7/20; G01M 3/16

(52) U.S. Cl. CPC H05K 7/20272; G01M 3/16

(57) ABSTRACT

A printed circuit board (PCB) includes a first vertical trace extending from a top surface of the PCB to a bottom surface of the PCB, and a second vertical trace extending from the top surface to the bottom surface, the second vertical trace being adjacent to the first vertical trace. The first vertical trace and the second vertical trace are configured such that a coolant liquid leaked onto the PCB acts to electrically connect the first vertical trace to the second vertical trace when the coolant liquid contacts the first vertical trace and the second vertical trace. The first vertical trace and the second vertical trace are further configured to provide a path for the coolant liquid to drain from the top surface to the bottom surface.

### FIELD OF THE DISCLOSURE

This disclosure relates to information handling systems, and more particularly relates to a printed circuit board (PCB) including a coolant liquid drain with integrated leak detection.

### BACKGROUND

As the value and use of information continues to increase, individuals and businesses seek additional ways to process and store information. One option is an information handling system. An information handling system generally processes, compiles, stores, and/or communicates information or data for business, personal, or other purposes.

Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A printed circuit board (PCB) may include a first vertical trace extending from a top surface of the PCB to a bottom surface of the PCB, and a second vertical trace extending from the top surface to the bottom surface, the second vertical trace being adjacent to the first vertical trace. The first vertical trace and the second vertical trace may be configured such that a coolant liquid leaked onto the PCB acts to electrically connect the first vertical trace to the second vertical trace when the coolant liquid contacts the first vertical trace and the second vertical trace. The first vertical trace and the second vertical trace may further be configured to provide a path for the coolant liquid to drain from the top surface to the bottom surface.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram of a direct liquid cooling (DLC) system according to an embodiment of the present disclosure;

FIGS. 2A, 2B and 2C illustrate a liquid coolant drain structure according to an embodiment of the present disclosure;

FIG. 3 illustrates a liquid coolant drain structure according to another embodiment of the present disclosure;

FIG. 4 illustrates a liquid coolant drain structure according to another embodiment of the present disclosure; and

FIG. 5 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

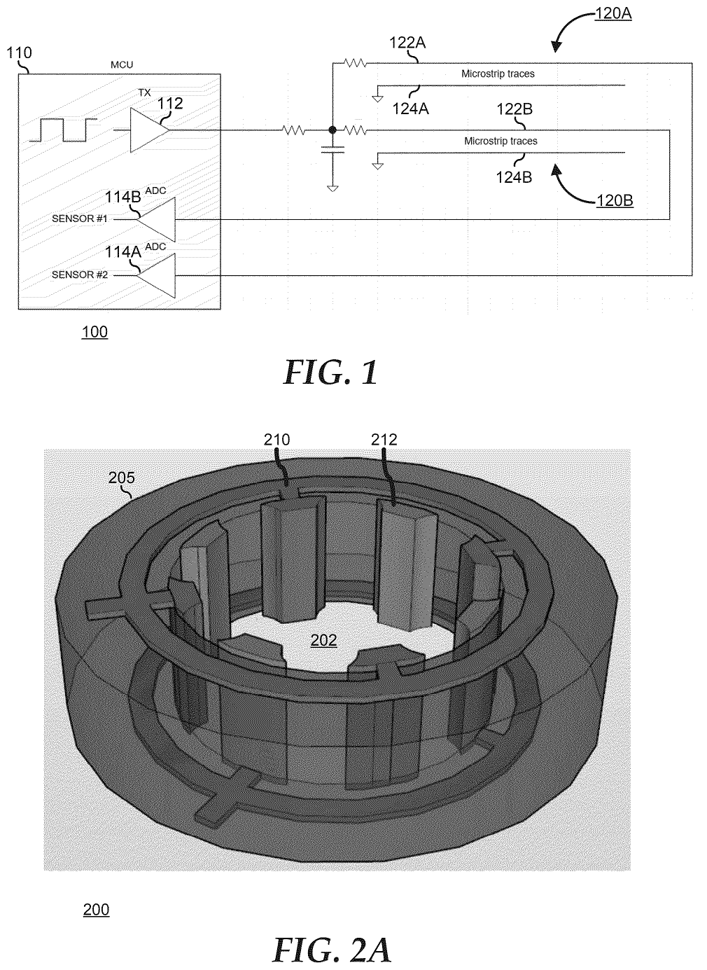

FIG. 1 illustrates a leak detection system 100. Leak detection system 100 represents a circuit that is typically associated with direct liquid cooling (DLC) systems cooling heat generating components of an information handling system. For example, DLC systems may be provided within datacenters to provide cooling for processors, memory modules, or other heat generating components within rack-mounted equipment of the datacenters. Such DLC systems may ease the burden of heat removal on the air chiller systems of the datacenter, permitting greater processing capabilities within existing datacenter infrastructure through the addition of separate liquid coolant handling systems.

However, it will be understood that the use of DLC systems within the rack-mounted equipment of a datacenter introduces new challenges to the datacenter environment. For example, the presence of coolant liquid comes with the risk of coolant leaks onto the sensitive electronic components of the equipment. In particular, leaked coolant liquid can short electronic circuits, causing data corruption or physical damage to the components of the equipment. Thus the timely detection of coolant liquid leaks is of paramount importance, and necessitates the introduction of additional components and control mechanisms to detect coolant leaks and to respond to the detection of coolant leaks.

Leak detection system 100 includes a microcontroller unit (MCU) 110 and detection trace pairs 120A and 120B. MCU 110 represents a controller configured to drive detection trace pairs 120A and 120B and to determine from received signals from the detection trace pairs whether or not a DLC system associated with the information handling system has developed a coolant liquid leak. MCU 110 includes a signal transmitter 112, a detector 114A (associated with detection trace pair 120A, and a detector 114B (associated with detection trace pair 120B). Detection trace pair 120A includes a source/detection signal trace 122A and a ground trace 124A. Similarly, detection trace pair 120B includes a source/detection signal trace 122B and a ground trace 124B. Detection trace pairs 120A and 120B represent signal traces, such as microstrip traces on a surface of a printed circuit board (PCB) of the information handling system. However, the PCB is fabricated such that detection trace pairs 120A and 120B are free from any solder mask or other passivation material, thereby exposing the detection trace pairs to the atmosphere. In a particular embodiment, signal trace 122 and ground trace 124 are fabricated with a geometry that is similar to various differential signal trace pairs, as needed or desired.

Signal transmitter 112 is resistively connected to signal/detection traces 122A and 122B to receive a driving signal. Signal/detection trace 122A is connected to detector 114A to detect the driving signal from signal transmitter 112. Similarly, signal/detection trace 122B is connected to detector 114B to detect the driving signal from signal transmitter 112. Ground traces 124A and 124B are each connected to a system ground plane of the PCB. Here, when a coolant leak of the DLC system bridges between one of source/detection signal trace 122A or 122B and respective ground trace 124A or 124B, the signal from signal transmitter 112 is provided with a high impedance path (due to the low conductivity of the coolant liquid) to the ground plane. The path to ground of the signal from signal transmitter 112 is detected by the associated one of detector 114A or 114B.

In a particular embodiment, detection trace pairs 120A and 120B represent two (2) separate leak detection circuits on the PCB. In particular, both detection trace pairs 120A and 120B can be located proximate to different leak-prone locations on the PCB of the information handling system. For example, detection trace pair 120A can be located proximate to a first coupler of the DLC system, and detection trace pair 120B can be located proximate to a second coupler of the DLC system. Furthermore, additional leak-prone locations on the PCB can be covered by the addition of one or more detection trace pair located proximate to the other leak-prone areas, as needed or desired.

In another embodiment, detection trace pairs 120A and 120B represent a single (1) leak detection circuit of the PCB. In particular, detection trace pair 120A can be located proximate to a particular leak-prone location on the PCB, and detection trace pair 120B can be located remotely from any leak-prone location on the PCB. Here, detection trace pair 120B may be understood to represent a reference trace pair that experiences similar aging, such as component degradation, corrosion, or the like, to detection trace pair 120A. More particularly, any aging related impedance changes in detection trace pair 120A will be mimicked in detection trace pair 120B, and the detection of a coolant leak can be made more accurately. Here, one or more additional detection trace pairs can be added to cover additional leak-prone locations of the PCB.

In a particular embodiment, the signal from signal transmitter 112 is a direct current signal at a predetermined voltage. Here, any drop in the voltage detected at detector 114A or 114B may be understood to represent a leak detection event, and such a detection scheme may likewise be understood to be a “leak/no leak” detection scheme. In another embodiment, the signal from signal transmitter 112 is a more complex signal such as a sine-wave signal at a predetermined frequency. Here a coolant leak may be understood to represent a more complex impedance change, and detectors 114A and 114B can be connected to a digital signal processor (DSP) configured to determine additional information, such as a magnitude of the leak, a location along the length of detection trace pairs 120A or 120B, or other information, as needed or desired. Remedial actions occurring on an information handling system in response to the detection of a coolant leak are known in the art and will not be described further herein, except as may be needed to illustrate the current embodiments.

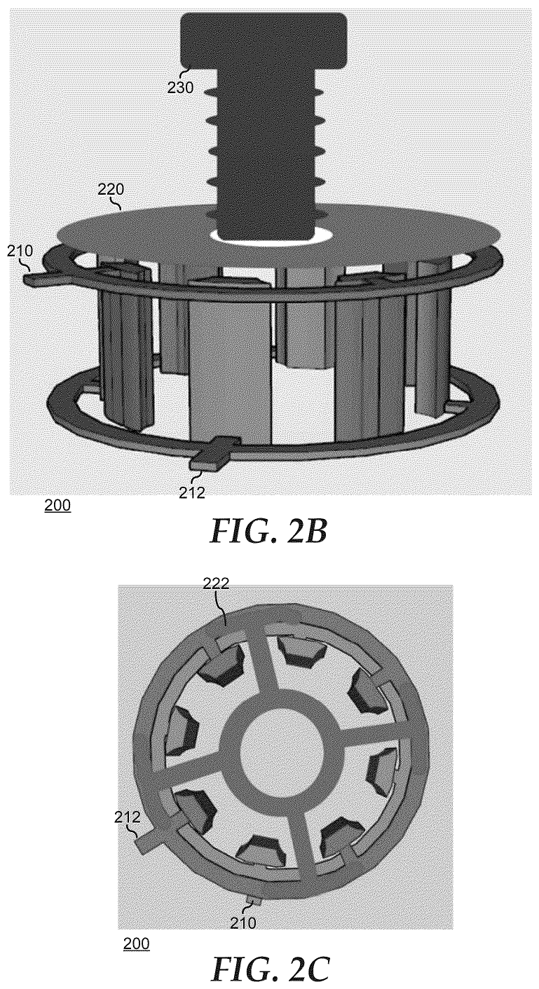

FIG. 2A illustrates a liquid coolant drain structure 200 that incorporates a detection trace pair that, in operation, operates similarly to detection trace pairs 120A and 120B. Liquid coolant drain structure 200 is incorporated into a hole 202 drilled into a PCB 205. In a particular case, the hole is fabricated utilizing a vertical conductive structure (VeCS) process that applies plated contacts around a perimeter of hole 202 in PCB 205. Here, as a fabrication process, eight (8) small holes can be drilled into PCB 205 to form eight (8) separate contacts. The eight (8) holes can then be plated utilizing known plated-through-hole techniques, as needed or desired. Next, hole 202 is drilled into PCB 205, thereby exposing eight electrical contacts formed as vertical traces around the perimeter of hole 202. Finally, traces are formed on a top surface of PCB 205 that connect alternating vertical traces to form a source/detection signal trace 210, and traces are formed on a bottom surface of the PCB that connect the remaining alternating vertical traces to form a ground trace 212. Signal trace 210 and ground trace 212 are then connected to a leak detection system similar to leak detection system 100. In a particular embodiment, liquid coolant drain structure 200 is located proximate to a leak-prone location of a DLC system associated with PCB 205. In this way, coolant liquid leaked from the DLC system proximate to liquid coolant drain structure 200 will simultaneously cause the leak detection system to detect the leaked coolant liquid through bridging of signal trace 210 and ground trace 212, and to prevent the leaked coolant liquid from pooling on the top surface of PCB 205 and to drain to the bottom of the PCB. In another case of utilizing the VeCS process, hole 202 can be drilled and plated. Then eight (8) small holes can be drilled in the sides of the plated hole to remove the conductive material, leaving the eight vertical traces.

FIG. 2B illustrates liquid coolant drain structure 200, including signal trace 210 and ground trace 212. Here, the detection and draining functions of liquid coolant drain structure 200 is improved by the addition of a washer 220 that is retained to the liquid coolant drain structure by a retention screw 230. Washer 220 is formed of a liquid-wicking material, such as a felt material, a cotton material, a synthetic fiber wicking material, or the like. In a particular embodiment, washer 220 is larger than hole 202, and can extend outward to cover a surface of PCB 205 that extends beyond the confines of liquid coolant drain structure 200 to provide leak detection and drainage of coolant liquid over a large area of the PCB.

FIG. 2C illustrates a bottom view of liquid coolant drain structure 200 including signal trace 210 and ground trace 212. Here, the functionality of liquid coolant drain structure 200 is expanded by the addition of a washer 222 affixed at the bottom of PCB 205. Here, washer 222 is formed of a hard plastic material and has voids that permit the leaked coolant liquid to drain through the washer. Further, washer 222 includes a threaded nut structure that permits the attachment of components to the top surface of PCB 205. For example, washer 222 may be utilized to affix large components to PCB 205, such as a heat sink, or other component, as needed or desired. In this way, liquid coolant drain structure 200 can be located proximate to high-heat generating components, such as CPUs, memory devices, or the like. Such locations may typically be cooled by the DLC system and my hence be considered to be a leak-prone location. Here, the real-estate of PCB 205 that is utilized in forming liquid coolant drain structure 200 may be offset by the dual use of affixing components to PCB 205. In a particular embodiment, not illustrated, a non-conductive threaded grommet can be inserted into hole 202 from the bottom side of PCB 205. The grommet can include the threaded nut structure to permit the attachment of components to the top surface of the PCB.

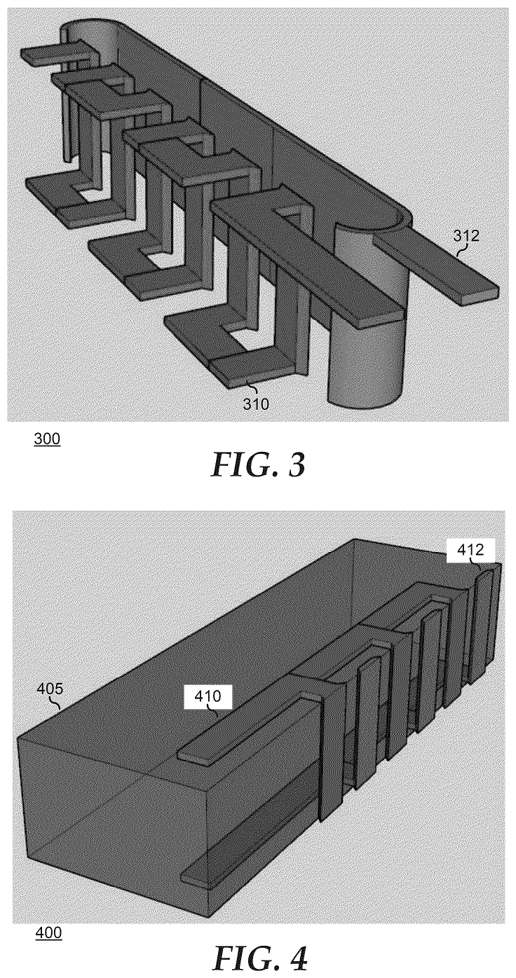

FIG. 3 illustrates a liquid coolant drain structure 300 similar to liquid coolant drain structure 200, that incorporates a detection trace pair including a signal trace 310 and a ground trace 312. Traces 310 and 312 operate similarly to detection trace pairs 120A and 120B, and to traces 210 and 212. Liquid coolant drain structure 300 is incorporated into a trench similar to hole 202 formed into a PCB. In particular, the trench is fabricated in the PCB utilizing the VeCS process that applies plated contacts around a perimeter of the trench. In a particular embodiment, one or more of signal trace 310 and ground trace 312 are formed as vertical traces formed along opposite sides of the trench, and that are connected together by circuit traces formed on a top surface and a bottom surface of the PCB. For example, signal trace 310 is herein illustrated as six (6) vertical traces formed along a left side of liquid coolant drain structure 200. Here, a ground trace can likewise be formed by six (6) vertical traces formed along a right side of the structure. In a particular case, the vertical traces can be connected by circuit traces formed on only one of the top surface or the bottom surface of the PCB. In another embodiment, one or more of signal trace 310 and ground trace 312 are formed as continuous traces formed along opposite sides of the trench, and that are connected to a circuit traces formed on the top surface or the bottom surface of the PCB. For example, ground trace 312 is herein illustrated as a continuous trace formed along a right side of liquid coolant drain structure 200. Here, a signal trace can likewise be formed by a continuous traces formed along a right side of the structure. In a particular embodiment, liquid coolant drain structure 300 is located proximate to a leak-prone location of a DLC system associated with the PCB. In this way, coolant liquid leaked from the DLC system proximate to liquid coolant drain structure 300 will simultaneously cause the leak detection system to detect the leaked coolant liquid through bridging of signal trace 310 and ground trace 312, and to prevent the leaked coolant liquid from pooling on the top surface of the PCB and to drain to the bottom of the PCB.

Note that liquid coolant drain structures 200 and 300 may differ in the size of hole 205 vis a vis the width of the trench. In particular, hole 205 may be fabricated with an arbitrarily large diameter, due to the alternating vertical traces of signal trace 210 and ground trace 212. Here, relatively small liquid coolant leaks may be expected to bridge the gap between at least one vertical trace of signal trace 210 and one vertical trace of ground trace 212. On the other hand, in liquid coolant drain structure 300, due to the fact that signal trace 310 is on an opposite side of the trench from ground trace 312, it will be understood that the width of the trench will need to be relatively narrow, in order to ensure that leaked liquid coolant bridges from one side of the trench to the opposite side to bridge between the signal trace and the ground trace.

FIG. 4 illustrates a liquid coolant drain structure 400 similar to liquid coolant drain structures 200 and 300, that incorporates a detection trace pair including a signal trace 410 and a ground trace 412. Traces 410 and 412 operate similarly to detection trace pairs 120A and 120B, to traces 210 and 212, and to traces 310 and 312. Liquid coolant drain structure 400 is incorporated into the edge of PCB 405. In particular, signal trace 410 and ground trace 412 are formed as alternating vertical traces formed along an edge of PCB 405. The vertical traces of signal trace 410 are connected together by a circuit trace formed on a top surface of PCB 405, and the vertical traces of ground trace 412 are connected together by a circuit trace formed on a bottom surface of the PCB. In a particular embodiment, one or more liquid coolant drain structures similar to liquid coolant drain structure 400 are formed around the edges of PCB 405. In a particular case, signal trace 410 and ground trace 412 can be formed around an entire perimeter of PCB 405, as needed or desired. In this way, any coolant liquid leak that reaches an edge of PCB 405 will be detected by liquid coolant drain structure 400.

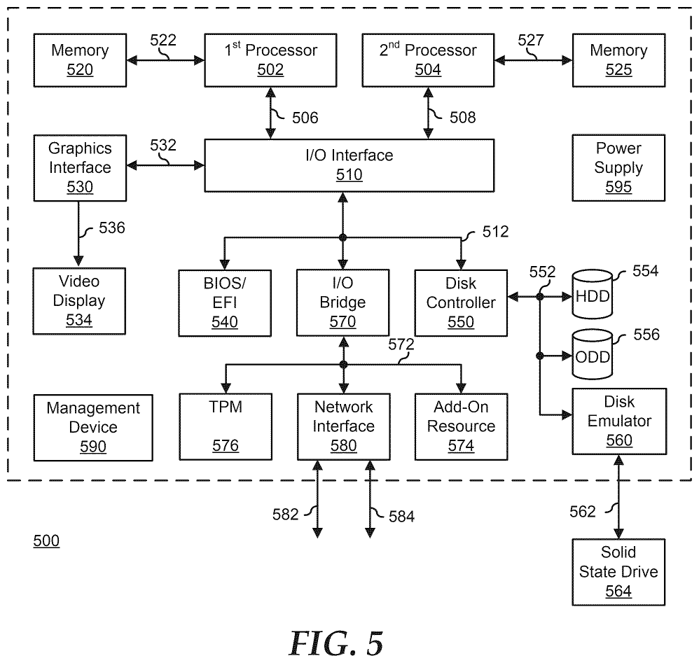

FIG. 5 illustrates a generalized embodiment of an information handling system 500 similar to information handling system 500. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below, and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 562, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 562, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532, and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 1394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512, or can be a different type of interface. As such, I/O bridge 570 extends the capacity of I/O channel 512 where peripheral interface 572 and the I/O channel are of the same type, and the I/O bridge translates information from a format suitable to the I/O channel to a format suitable to the peripheral channel 572 where they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500. Management device 590 can operate off of a separate power plane from the components of the host environment so that the management device receives power to manage information handling system 500 where the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed:

1. A printed circuit board (PCB), comprising:
a first vertical trace extending from a top surface of the PCB to a bottom surface of the PCB;
a second vertical trace extending from the top surface to the bottom surface, the second vertical trace being adjacent to the first vertical trace; and
wherein the first vertical trace and the second vertical trace are configured such that a coolant liquid leaked onto the PCB acts to electrically connect the first vertical trace to the second vertical trace when the coolant liquid contacts the first vertical trace and the second vertical trace, and are further configured to provide a path for the coolant liquid to drain from the top surface to the bottom surface.

2. The PCB of claim 1, further comprising:
a hole through the PCB extending from the top surface to the bottom surface, wherein the first vertical trace and the second vertical trace are disposed within the hole.

3. The PCB of claim 2, wherein the hole is further provided to mount a component to the PCB.

4. The PCB of claim 3, further comprising:
a washer fitted to the hole on the bottom surface, the washer including voids to permit the coolant liquid to drain through the washer.

5. The PCB of claim 4, wherein the washer includes a threaded nut structure that permits an attachment of the component to the top surface.

6. The PCB of claim 2, further comprising:
a third vertical trace disposed within the hole, the third vertical trace being adjacent to the second vertical trace and coupled to the first vertical trace; and
a fourth vertical trace disposed within the hole, the fourth vertical trace being adjacent to the third vertical trace and coupled to the second vertical trace.

7. The PCB of claim 1, further comprising:
a trench through the PCB extending from the top surface to the bottom surface, wherein the first vertical trace is disposed on a first side of the trench and the second vertical trace is disposed on a second side of the trench.

8. The PCB of claim 7, wherein the first vertical trace is formed continuously on the first side of the trench.

9. The PCB of claim 7, further comprising:
a third vertical trace disposed on the first side of the trench, the third vertical trace being adjacent to the first vertical trace and coupled to the first vertical trace.

10. The PCB of claim 1, wherein the first vertical trace and the second vertical trace are each formed on an edge of the PCB.

11. A method, comprising:
providing, in a printed circuit board (PCB), a first vertical trace extending from a top surface of the PCB to a bottom surface of the PCB; and
providing, in the PCB, a second vertical trace extending from the top surface to the bottom surface, the second vertical trace being adjacent to the first vertical trace,
wherein the first vertical trace and the second vertical trace are configured such that a coolant liquid leaked onto the PCB acts to electrically connect the first vertical trace to the second vertical trace when the coolant liquid contacts the first vertical trace and the second vertical trace, and are further configured to provide a path for the coolant liquid to drain from the top surface to the bottom surface.

12. The method of claim 11, further comprising:
providing, in the PCB, a hole extending from the top surface to the bottom surface, wherein the first vertical trace and the second vertical trace are disposed within the hole.

13. The method of claim 12, further comprising:
mounting a component to the PCB through the hole.

14. The method of claim 13, further comprising:
fitting a washer to the hole on the bottom surface, the washer including voids to permit the coolant liquid to drain through the washer.

15. The method of claim 14, wherein the washer includes a threaded nut structure that permits an attachment of the component to the top surface.

16. The method of claim 12, further comprising:
providing, in the PCB, a third vertical trace disposed within the hole, the third vertical trace being adjacent to the second vertical trace and coupled to the first vertical trace; and
providing, in the PCB, a fourth vertical trace disposed within the hole, the fourth vertical trace being adjacent to the third vertical trace and coupled to the second vertical trace.

17. The method of claim 11, further comprising:
providing, in the PCB, a trench extending from the top surface to the bottom surface, wherein the first vertical trace is disposed on a first side of the trench and the second vertical trace is disposed on a second side of the trench.

18. The method of claim 17, wherein the first vertical trace is formed continuously on the first side of the trench.

19. The method of claim 17, further comprising:
providing, in the PCB, a third vertical trace disposed on the first side of the trench, the third vertical trace being adjacent to the first vertical trace and coupled to the first vertical trace.

20. A printed circuit board (PCB), comprising:
a leak detection system;
a first vertical trace extending from a top surface of the PCB to a bottom surface of the PCB, the first vertical trace being coupled to a first input of the leak detection system; and
a second vertical trace extending from the top surface to the bottom surface, the second vertical trace being adjacent to the first vertical trace, the second vertical trace being coupled to a second input of the leak detection system,
wherein the leak detection system is configured to detect when a coolant liquid is leaked onto the PCB when the coolant liquid bridges the first vertical trace and the second vertical trace, and
wherein the first vertical trace and the second vertical trace are further configured to provide a path for the coolant liquid to drain from the top surface to the bottom surface.
